(19) United States
(12) Patent Application Publication
(10) Pub. No.: US 2006/0203591 A1
(43) Pub. Date: Sep. 14, 2006

(54) One time programmable read-only memory comprised of fuse and two selection transistors

(76) Inventor: Dong Kyu Lee, Suwon (KR)

Correspondence Address: FENWICK & WEST LLP, SILICON VALLEY CENTER, 801 CALIFORNIA STREET, MOUNTAIN VIEW, CA, 94041, US

(21) Appl. No.: 11/078,571

(22) Filed: Mar. 11, 2005

(51) Int. Cl. G11C 17/18

(52) U.S. Cl. 365/225.7

(57) ABSTRACT

A one time programmable read-only memory (OTPROM) device includes a plurality of memory cells, where a memory cell of the OTPROM device comprises a fuse indicating a first memory state of the memory cell if the fuse is destroyed and a second memory state of the memory cell if the fuse is not destroyed, a first transistor coupled to the fuse, and a second transistor serially coupled to the first transistor. Both the first transistor and the second transistor are turned on to select the memory cell, and at least one of the first transistor and the second transistor are turned off to unselect the memory cell. The fuse insulation layer of the fuse and the gate insulation layers of the first and second transistors share a common insulation layer formed in the same fabrication process.

### TECHNICAL FIELD

The present invention relates to a one time programmable read-only memory (OTPROM) and, more specifically, to an OTPROM including memory cells each comprised of a fuse and two serially connected selection transistors and methods of operating and fabricating such OTPROM.

### BACKGROUND OF THE INVENTION

OTPROMs are semiconductor storage devices that can be programmed or written only once. OTPROMs are similar to erasable programmable read-only memories (EPROMs) in that they can be programmed, but are different from EPROMs in that OTPROMs have no means for erasing the stored content while the content stored in EPROMs can be erased with ultraviolet through a quart glass window in the EPROMs. OTPROMS are widely used where smaller package size is needed.

FIG. 1 is a top view of the layout of a conventional OTPROM device formed on a semiconductor wafer, and FIG. 2 is a cross-sectional view of the semiconductor wafer of a memory cell of a conventional OTPROM device across the line Y-Y′ of FIG. 1. Such conventional OTPROM devices are shown in, for example, U.S. Pat. No. 6,667,902 issued on Dec. 23, 2003 to Peng.

Referring to FIGS. 1 and 2, a memory cell 20 of the OTPROM includes (i) a fuse 11 comprised of a fuse electrode 15, a fuse insulation layer 10, and a buried junction layer 9, and (ii) a selection transistor 19 comprised of a source region 17, a gate electrode 16, a gate insulation layer 12, and a drain region 18, all of which are formed on the active region of the semiconductor substrate 5. In one embodiment, the active region is formed of P-type semiconductor and the junction layer 9, and the drain region 18, and the source region 17 are formed of N-type semiconductor material. A voltage Vcc to the bit line 13 is applied to the fuse 11 via the metal contact 14. A high voltage Vcc applied to the fuse 11 relative to the voltage at the junction region 9 destroys the fuse 11.

A destroyed fuse 11 indicates the memory cell 20 in a first state, such as “1” while an undestroyed fuse 11 indicates the memory cell 20 in a second state, such as “0.” In order to read data from the memory cell 20, a voltage Vread higher than the threshold turn-on voltage of the selection transistor 19 is applied to the gate electrode 16 via a word line (not shown) and the source 17 is connected to Ground (zero volt) to turn on the selection transistor 19.

If the fuse 11 is destroyed, then a conduction path is formed from the bit line 13 to the source electrode 17, thereby indicating the memory cell 20 in a first state, such as “1.” If the fuse 11 is not destroyed, then a conduction path cannot be formed from the bit line 13 to the source electrode 17, thereby indicating the memory cell 20 in a second state, such as “0.”

The gate insulation layer 12 is thicker than the fuse insulation layer 10. This is necessary in conventional OTPROMs to prevent the gate insulation layer 12 from also being destroyed when the fuse insulation layer 10 is destroyed, in response to a voltage Vcc high enough to destroy the fuse 11. However, having a gate insulation layer 12 and a fuse insulation layer 10 with different thicknesses complicates the process for fabricating the conventional OTPROM, as will be clear from FIGS. 3A-3H.

FIGS. 3A-3H are cross-sectional views of the semiconductor wafer of a memory cell of a conventional OTPROM device across the line Y-Y′ of FIG. 1, illustrating the process for fabricating the conventional OTPROM. Referring to FIG. 3A, the gate insulation layer 12 (e.g., silicon dioxide) for the selection transistor 19 is formed on the active region of semiconductor substrate 5. Referring to FIG. 3B, the gate insulation layer 12 is removed where the fuse 11 will be formed, using photolithography with the photoresistor layer 22, to prevent the gate insulation layer 12 in the selection transistor region 23 from being removed.

Referring to FIG. 3C, the photoresistor layer 22 is removed and the fuse insulation layer 10 is grown using thermal oxidation. Thermal oxidation also causes the gate insulation layer 12 to grow thicker, resulting in the gate insulation layer 12 being thicker than the fuse insulation layer 10. Note that depositing the photoresistor layer 22 on the gate insulation layer 10 and thereafter removing it degrade the quality of the gate insulation layer 12.

However, referring to FIG. 3D, there is a possibility that the photoresistor layer 22 may be misaligned 25 such that the gate insulation layer 12 is removed up to where the selection transistor 19 should be formed. Referring to FIG. 3E, such misalignment 25 would result in the gate insulation layer 12 being thinner 26 than normal under the gate electrode 16 after the thermal oxidation process illustrated in FIG. 3C is performed.

Referring to FIG. 3F there is also a possibility that the photoresistor layer 22 may be misaligned 27 such that the gate insulation layer 12 is not removed where the fuse 19 is to be formed. Referring to FIG. 3G, such misalignment 27 would result in the fuse insulation layer 10 being thicker 28 under the fuse electrode 15 than normal after the thermal oxidation process illustrated in FIG. 3C is performed.

In order to prevent the gate insulation layer 12 from being thinner 26 than normal due to such misalignment 25 or the fuse insulation layer 10 from being thicker than normal due to such misalignment 27, the distance between the fuse electrode 15 and the gate electrode 16 is set to be at least as large as the misalignment margins 29, 30. This results in an unnecessarily large cell size for the conventional OTPROM. Note that this disadvantage of the conventional OTPROM is caused by the requirement that the gate insulation layer 12 should be thicker than the fuse insulation layer 10 in conventional OTPROMs to prevent the gate insulation layer 12 from also being destroyed when the fuse insulation layer 10 is destroyed, in response to a voltage Vcc high enough to destroy the fuse 11.

Therefore, there is a need for an OTPROM structure that obviates the need for the gate insulation layer to be thicker than the fuse insulation layer. There is also a need for a simpler process for fabricating the OTPROM that obviates the addition of misalignment margins. There is also a need for a simpler process for fabricating the OTPROM that obviates depositing a photoresistor layer on the gate insulation layer that degrades the quality of the gate insulation layer.

### SUMMARY OF THE INVENTION

The present invention provides a one time programmable read-only memory (OTPROM) device having a plurality of memory cells, where each memory cell of the OTPROM device comprises a fuse indicating a first memory state of the memory cell if the fuse is destroyed and a second memory state of the memory cell if the fuse is not destroyed, a first transistor coupled to the fuse, and a second transistor serially coupled to the first transistor. Both the first transistor and the second transistor are turned on to select the memory cell, and at least one of the first transistor and the second transistor are turned off to unselect the memory cell.

To select the memory cell and destroy the fuse during a write operation to the OTPROM, a first voltage, a second voltage, and a third voltage are applied to the fuse electrode of the fuse, the gate electrode of the first transistor, and the gate electrode of the second transistor, respectively, where the first voltage is higher than a threshold breakdown voltage of the fuse insulation layer of the fuse and the second voltage and the third voltage are lower than the first voltage. In one embodiment, the third voltage is substantially same as the second voltage. In another embodiment, the second voltage and the third voltage are substantially half of the first voltage. Note that the difference between the first voltage and the second voltage is set lower than the threshold breakdown voltage of the gate insulation layer of the first transistor, so that the gate insulation layer of the first transistor in an unselected memory cell is not destroyed during the write operation to the selected memory cell connected to the unselected memory cell.

To unselect a memory cell during the write operation to the OTPROM, a first voltage, a second voltage, and a third voltage are applied to the fuse electrode of the fuse, the gate electrode of the first transistor, and the gate electrode of the second transistor, respectively, where the third voltage is set lower than both the second voltage and the threshold turn-on voltage of the second transistor. This ensures that at least the second transistor is turned off, so that the memory cell is not selected. In one embodiment, the third voltage is substantially zero volt.

To select the memory cell during a read operation from the OTPROM, a first voltage, a second voltage, and a third voltage are applied to the fuse electrode of the fuse, the gate electrode of the first transistor, and the gate electrode of the second transistor, respectively, where the second voltage and the third voltage are higher than threshold turn-on voltages of the first transistor and the second transistor, respectively, to turn on both the second transistor and the third transistor. In one embodiment, the first voltage, the second voltage, and the third voltage are substantially the same.

To unselect the memory cell during the read operation from the OTPROM, a first voltage, a second voltage, and a third voltage are applied to the fuse electrode of the fuse, the gate electrode of the first transistor, and the gate electrode of the second transistor, respectively, where the third voltage is lower than a threshold turn-on voltage of the second transistor. In one embodiment, the third voltage is zero volt. In another embodiment, the second voltage and the third voltage are the same. In still another embodiment, the second voltage is higher than the third voltage and the threshold turn-on voltage of the first transistor, but the memory cell is still unselected even if the first transistor is turned on because the second transistor is still off.

The OTPROM of the present invention is fabricated such that the fuse insulation layer of the fuse has substantially the same thickness as the thickness of the gate insulation layer of the first transistor and the thickness of the gate insulation layer of the second transistor. This is possible, because the fuse insulation layer, the gate insulation layer of the first transistor, and the gate insulation layer of the second transistor are parts of a common insulation layer formed in a single oxidation process of the semiconductor substrate. In one embodiment, the first transistor and the second transistor are MOSFETs (Metal-Oxide-Silicon Field Effect Transistors).

The OTPROM of the present invention has the advantage that the OTPROM structure is simple with the thickness of the gate insulation layer of the selection transistors being substantially same as that of the fuse insulation layer. This results in a much simpler process for fabricating the OTPROM, because misalignment margins need not be added in the fabrication process.

### BRIEF DESCRIPTION OF THE DRAWINGS

The teachings of the present invention can be readily understood by considering the following detailed description in conjunction with the accompanying drawings. Like reference numerals are used for like elements in the accompanying drawings.

FIG. 1 is a top view of the layout of a conventional OTPROM device formed on a semiconductor wafer.

FIG. 2 is a cross-sectional view of the semiconductor wafer of a memory cell of a conventional OTPROM device across the line Y-Y′ of FIG. 1.

FIGS. 3A-3H are cross-sectional views of the semiconductor wafer of a memory cell of a conventional OTPROM device across the line Y-Y′ of FIG. 1, illustrating the process for fabricating the conventional OTPROM.

FIG. 4 is a top view of the layout of an OTPROM device formed on a semiconductor wafer, according to one embodiment of the present invention.

FIG. 5 is a cross-sectional view of the semiconductor wafer of a memory cell of the OTPROM device across the line Y-Y′ of FIG. 4, according to one embodiment of the present invention.

FIGS. 6A-6E are cross-sectional views of the semiconductor wafer of a memory cell of the OTPROM device across the line Y-Y′ of FIG. 4, illustrating the process, for fabricating the OTPROM according to one embodiment of the present invention.

FIG. 7A is a cross-sectional view of the semiconductor wafer of two memory cells of the OTPROM device illustrating the operation of the OTPROM, according to one embodiment of the present invention.

FIG. 7B is an equivalent circuit diagram illustrating the write operation to a selected OTPROM cell to destroy the fuse, according to one embodiment of the present invention.

FIG. 7C is an equivalent circuit diagram illustrating the write operation to an unselected OTPROM cell where the fuse has been previously destroyed by an earlier writing operating, according to one embodiment of the present invention.

FIG. 7D is an equivalent circuit diagram illustrating the write operation to an unselected OTPROM cell where the fuse has not been previously destroyed by an earlier operation, according to one embodiment of the present invention.

FIG. 7E is an equivalent circuit diagram illustrating the read operation from both a selected OTPROM cell and an unselected OTPROM cell, according to one embodiment of the present invention.

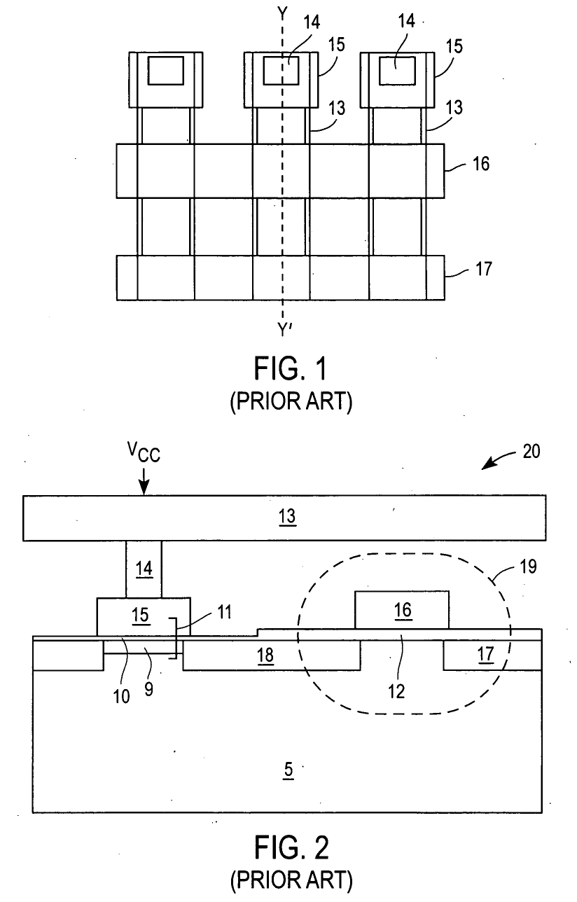

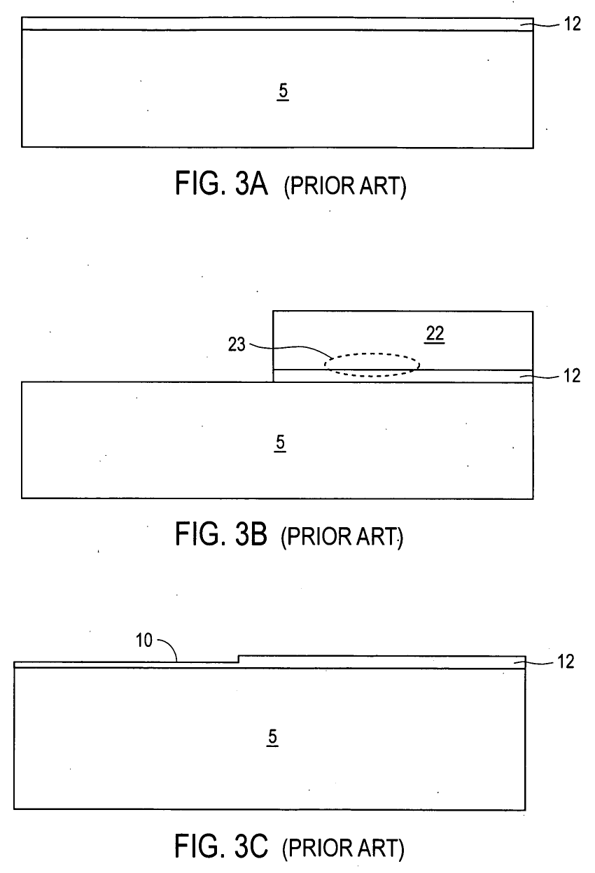

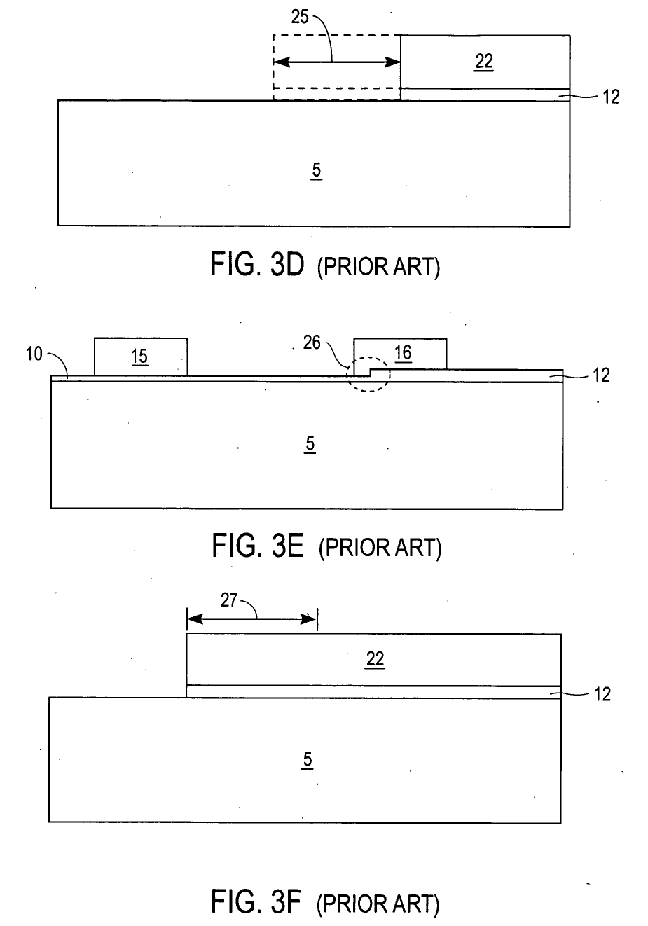

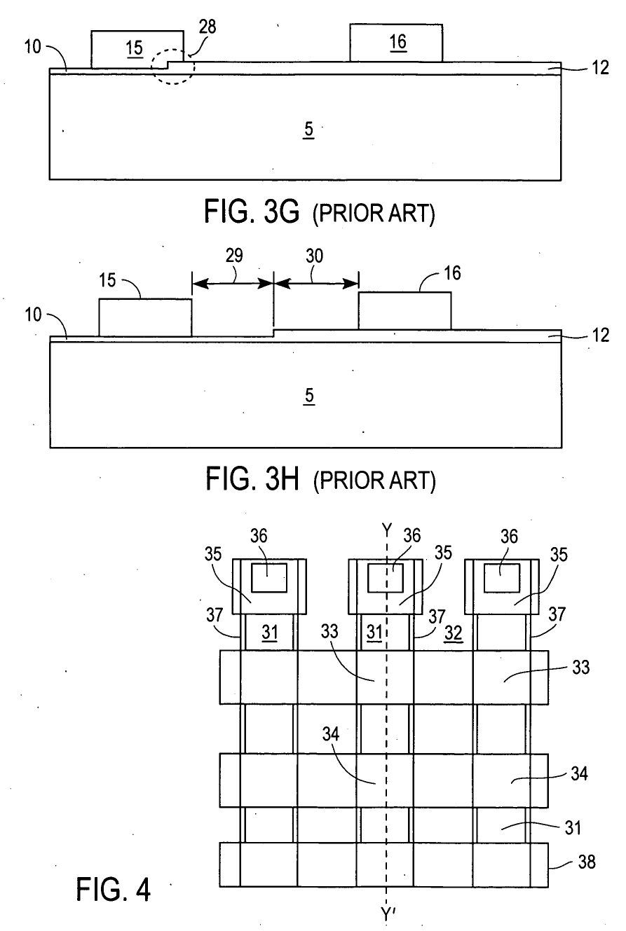

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF EMBODIMENTS

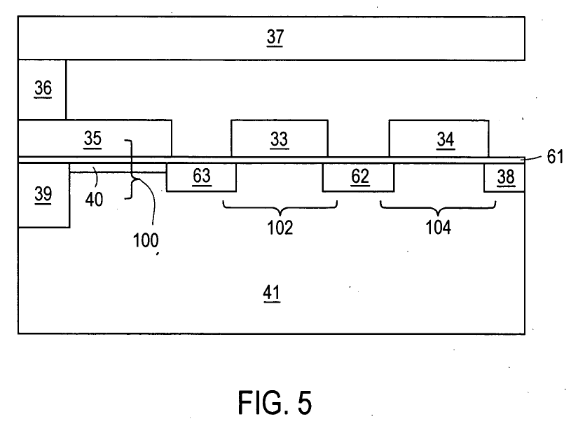

FIG. 4 is a top view of the layout of an OTPROM device formed on a semiconductor wafer, according to one embodiment of the present invention, and FIG. 5 is a cross-sectional view of the semiconductor wafer of a memory cell of the OTPROM device across the line Y-Y′ of FIG. 4, according to one embodiment of the present invention. Referring to FIGS. 4 and 5, the memory cells of the OTPROM are formed on the active regions 31 longitudinally formed on the substrate 41. The active regions 31 are separated by field regions 32 longitudinally formed between the active regions 31.

Each memory cell of the OTPROM includes a fuse 100, a first selection transistor 102, and a second selection transistor 104. The fuse 100 is comprised of a buried junction layer 40, an insulation layer 61, and a fuse electrode 35. The fuse electrode 35 is located at one end of the active region 31. The first selection transistor 102 is comprised of a drain region 63, a source region 62, the gate insulation layer 61, and the gate electrode 33. The second selection transistor 104 is comprised of a drain region 62, a source region 61, the gate insulation layer 61, and the gate electrode 34.

A contact hole 36 is formed on the fuse electrode 35 and the bit line metal pattern 37 is formed on the contact hole 36. Word lines (not shown) are also connected to the gate electrodes 33, 34. That is, each memory cell of the OTPROM has two word lines associated with it, and each word line is coupled to one of the two selection transistors. Appropriate voltages are applied to the bit line and the two word lines to select a particular memory cell of the OTPROM and to write or read data to/from the particular memory cell according to the present invention, as will be explained in greater detail below.

Each memory cell is separated from another memory cell of the OTPROM by field oxide 39. Note that the region 62 serves as the source for the first selection transistor 102 as well as the drain for the second selection transistor 104. Also note that the insulation layer 61 serves as the gate insulation layers for both the first and the second selection transistors 102, 104 as well as functioning as the fuse insulation layer for the fuse 100.

In one embodiment, the active region 31 is formed of P-type silicon, in which case the junction layer 40 is formed of N⁻ type silicon and the source-drain regions 63, 62, and 38 are formed of N⁺ type silicon. In another embodiment, the active region 31 is formed of N-type doped silicon, in which case the junction layer 40 is formed of P⁻ type silicon and the source-drain regions 63, 62, and 38 are formed of P⁺ type silicon.

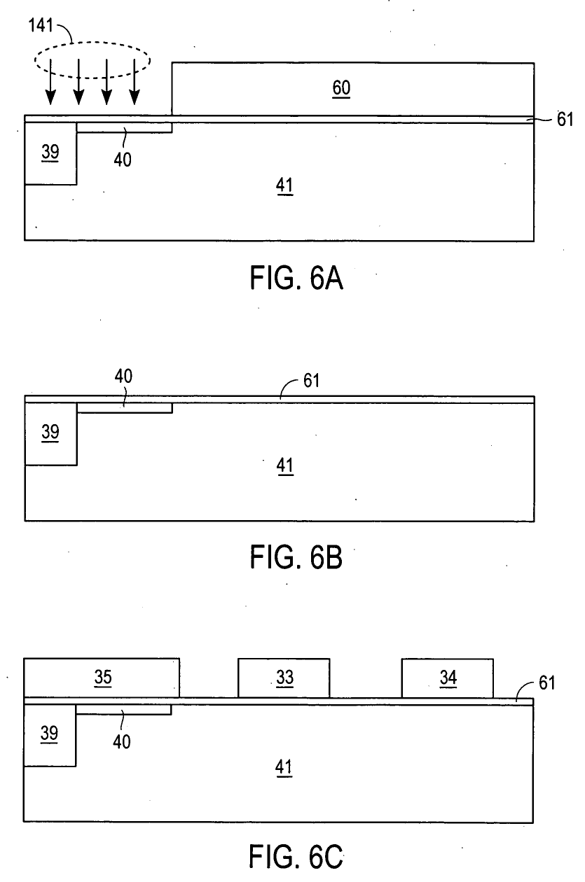

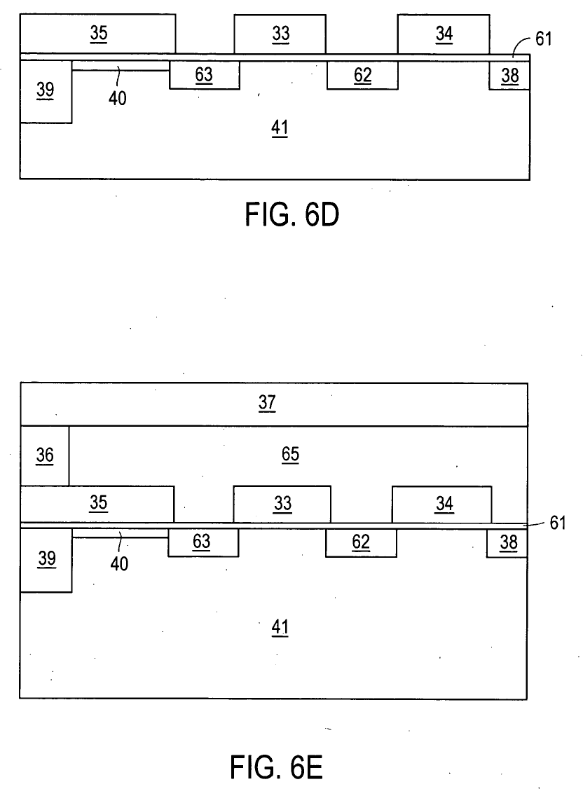

FIGS. 6A-6E are cross-sectional views of the semiconductor wafer of a memory cell of the OTPROM device across the line Y-Y′ of FIG. 4, illustrating the process for fabricating the OTPROM according to one embodiment of the present invention. Referring to FIG. 6A, with the active region 31 and the field oxide 39 already formed, the insulation layer 61 (typically silicon dioxide) is grown on the active region 31 by thermal oxidation, and a photoresistor layer 60 is deposited on the insulation layer 61. Part of the photoresistor layer 60 is removed where the junction layer 40 is to be formed, using photolithography, and the N⁻ type junction layer 40 is formed by ion implantation 141. Note that the junction layer 40 may be omitted if the overlap between the fuse electrode 35 and the field oxide 39 is very small, such as 0.2 μm.

Referring to FIG. 6B, the photoresistor layer 60 is then removed to expose the insulation layer 61. In one embodiment, the insulation layer 61 is 6 nm thick. In another embodiment, the insulation layer 61 is not thicker than 4 nm, when the voltage applied to the gate electrodes 33 and 34 to select the transistors 102, 104 is 6 volts.

Referring to FIG. 6C, the gate electrodes 33, 34 and the fuse electrode 35 are formed on the insulation layer 61 at the same time. This is possible because the insulation layer 61 is used as both the gate insulation layers of the selection transistors 102, 104 and the fuse insulation layer for the fuse 100.

Because the gate electrodes 33, 34 and the fuse electrode 35 are formed in the same process, the process for fabricating the OTPROM of the present invention is much simpler than that for a conventional OTPROM. In one embodiment, the gate electrodes 33, 34 are formed of polysilicon doped with impurities. In another embodiment, the gate electrodes 33, 34 are formed of silicide (WSix, TiSix, or CoSix) to reduce the resistance associated with the gate electrodes 33, 34.

Referring to FIG. 6D, the source-drain regions 63, 62, and 38 are formed using ion implantation. Referring to FIG. 6E, the inter-layer dielectric 65 is formed over the fuse electrode 35, the gate electrodes 33, 34, and the insulation layer 61. The top of the inter-layer dielectric 65 is polished (not shown) using a CMP (chemical-mechanical polishing) process. A contact hole 36 is opened in the inter-layer dielectric 65, and the bit line 37 is formed using a metallization process.

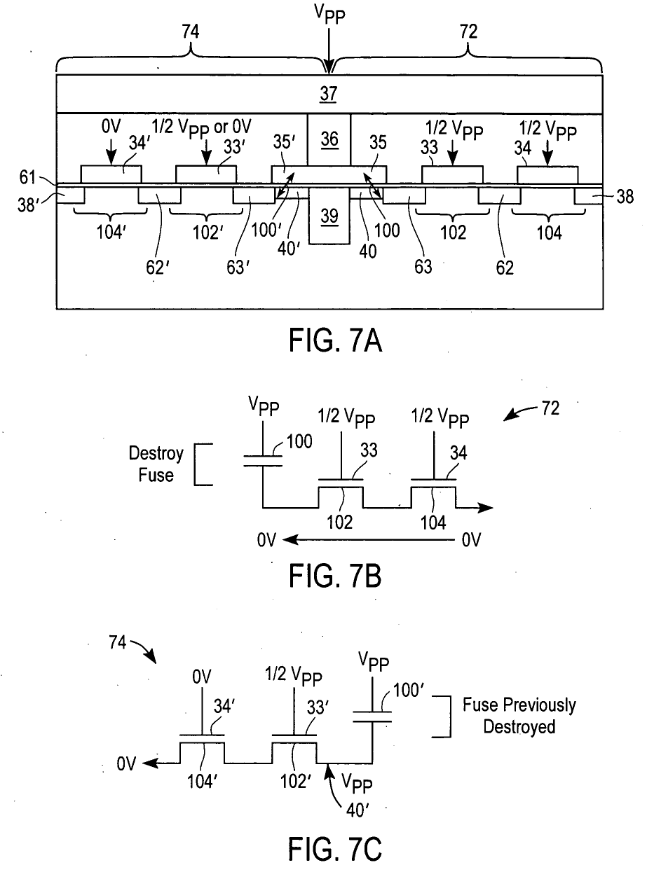

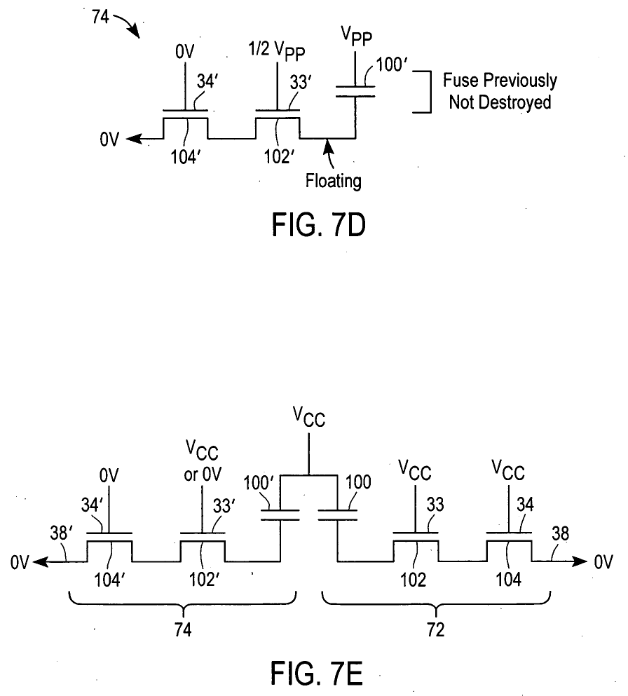

FIG. 7A is a cross-sectional view of the semiconductor wafer for two memory cells 702, 704 of the OTPROM device, illustrating the operation of the OTPROM according to one embodiment of the present invention, and FIG. 7B is an equivalent circuit diagram illustrating the write operation to a selected OTPROM cell 72 to destroy the fuse 100, according to one embodiment of the present invention. Referring to FIGS. 7A and 7B, the memory cell 72 is selected by applying a voltage Vpp (6 volts if the insulation layer 61 is approximately 3-4 nm thick) to the bit line 37 and by applying a voltage lower than Vpp (e.g., ½ Vpp) to both gate electrodes 33, 34 of the selection transistors 102, 104, respectively, and by applying 0 volt to the source 38 of the selection transistor 104.

The voltage Vpp is at least as high as a voltage that would induce an electric filed of 15 MV/cm to the fuse insulation layer 61 if the insulation layer is formed of silicon dioxide. The voltage ½ Vpp applied to the gate electrodes 33, 34 can be modified to be any value between approximately 1-5 volts. As explained previously, the gate electrodes 33, 34 are connected to the two word lines (not shown) corresponding to the OTPROM cell 72.

By applying ½ Vpp to both gate electrodes 33, 34 of the selection transistors 102, 104, respectively, and 0 volt to the source 38 of the selection transistor 104, both selection transistors 102, 104 are turned on. Thus, a conduction path from the source 38 (connected to 0 volt) to the fuse 100 is formed. With Vpp applied to one side of the fuse 100 and 0 volt applied to the other side of the fuse, the fuse 100 is destroyed.

FIG. 7C is an equivalent circuit diagram illustrating the writing operation to an unselected OTPROM cell where the fuse has been previously destroyed by an earlier writing operation, according to one embodiment of the present invention. In other words, FIG. 7C illustrates a memory cell 74 that is not selected while a writing operation to destroy the fuse 100 is being conducted on another memory cell 72 connected to the memory cell 74, as shown in FIGS. 7A and 7B. In the example of FIG. 7C, the fuse 100′ of the memory cell 74 is shown previously destroyed by an earlier operation on the memory cell 74.

As shown in FIG. 7C, when the memory cell 74 is not to be selected, Vpp (or floating voltage) is applied to the fuse electrode 35′ of the fuse 100′ and voltages of ½ Vpp and 0 volt are applied to the word lines (not shown) connected to the gate electrodes 33′, 34′, respectively. Since the fuse 100′ was previously destroyed and is conducting, the voltage Vpp is in turn applied to the junction layer 40′ of the fuse 100′ and to the drain region 63′ of the selection transistor 102′. Thus, the voltage applied to the gate insulation layer 61 of the transistor 102′ is merely Vpp-½Vpp (approximately 3V) and thus the gate insulation layer 61 is not destroyed. Note that the gate insulation layer 61 is not destroyed even though the thickness of the gate insulation layer 61 is not thicker than that of the fuse insulation layer 61 of the fuse 100′.

Applying a voltage (e.g., zero volt) lower than the threshold turn-on voltage of the second selection transistor 104′ to the gate electrode 34′ ensures that the memory cell 74 is not selected even though a voltage ½ Vpp (not 0 volt) is applied to the gate electrode 33′ of the first selection transistor 102′. This is possible because the second selection transistor 104′, when turned off, blocks the conduction path from ground via the selection transistors 104′, 102′ and the fuse 100′ regardless of the conduction state of the first selection transistor 102′. In other words, even if the voltage ½ Vpp is larger than the threshold turn-on voltage of the selection transistor 102′, the second transistor 104′ would still be off and the memory cell 74 would still be unselected.

FIG. 7D is an equivalent circuit diagram illustrating the write operation to an unselected OTPROM cell where the fuse has not been previously destroyed by an earlier operation, according to one embodiment of the present invention. In other words, FIG. 7D illustrates a memory cell 74 that is not selected while a write operation to destroy the fuse 100 is being conducted on another memory cell 72 connected to the memory cell 74 as shown in FIGS. 7A and 7B. In the example of FIG. 7D, the fuse 100′ of the memory cell 74 is shown not destroyed previously by an earlier operation on the memory cell 74.

As shown in FIG. 7D, when the memory cell 74 is not to be selected, Vpp (or floating voltage) is applied to the fuse electrode 35′ of the fuse 100′ and voltages of V₂ Vpp and 0 volt are applied to the word lines (not shown) connected to the gate electrodes 33′, 34′, respectively. Since the fuse 100′ was not previously destroyed and is not conducting, the voltage at the junction layer 40′ of the fuse 100′ and the drain region 63′ of the selection transistor 102′ is floating. Thus, the gate insulation layer 61 is not destroyed. Again, note that the gate insulation layer 61 is not destroyed even though the thickness of the gate insulation layer 61 is not thicker than that of the fuse insulation layer 61 of the fuse 100′.

FIG. 7E is an equivalent circuit diagram illustrating the read operation from both a selected OTPROM cell 72 and an unselected OTPROM cell 74. To read data from a selected memory OTPROM cell 72, a voltage Vcc (e.g., 1.8 V) lower than Vpp (e.g., 6 V) is applied to the fuse electrode 35 of the fuse 100 via the bit line 37 and to the two gate electrodes 33, 34 via the two word lines (not shown). Vcc is set higher than the threshold turn-on voltages of the two selection transistors 102, 104.

If the fuse 100 was previously destroyed, a conduction path is formed from the source 38 to the bit line 37 via the two selection transistors 102, 104 and the fuse 100, thereby indicating a first state (e.g., “1”) of the selected memory cell 72. If the fuse 100 was not previously destroyed, a conduction path cannot be formed from the source 38 to the bit line 37 even though the two selection transistors 102, 104 are turned on, thereby indicating a second state (e.g., “0”) of the selected memory cell 24.

Note that, in one embodiment, 0 volt is applied to the gate electrodes 33′, 34′ of the selection transistors 102′, 104′ of the unselected memory cell 74. Therefore, the two selection transistors 102′, 104′ are turned off, and no conduction path can be formed from the source 38′ to the fuse 100′ regardless of the state of the fuse 100.′ In another embodiment, Vcc (rather than 0 V) is applied to the gate electrode 33′ of the unselected memory cell 74. Still, no conduction path is formed from the source 38′ to the fuse 100′ regardless of the conduction state of the first selection transistor 102′, because the second selection transistor 104′ is still off.

Table 1 below illustrates the various voltages to be applied to the fuse electrodes 35, 35′ (via bit line 37), the gate electrodes 33, 34 (33′, 34′) (via the first and second word lines, respectively), and the source regions 38, 38′ for the write and read operations of the memory cells 72, 74 of the OTPROM. In one embodiment, Vpp is approximately 6 V and Vcc is approximately 1.8 V where the insulation layer 61 is a silicon dioxide layer that is about 3-4 nm thick.

TABLE 1

| | Write Mode | Read Mode |
|---|---|---|
| Fuse Electrode 35 (Bit Line | Vpp | Vcc |
| 37) - Selected Cell | | |
| Fuse Electrode 35′ (Bit Line | Floating (or Vpp) | Floating (or Vcc) |
| 37) - Unselected Cell | | |
| Gate Electrode 33 (First Word | ½ Vpp | Vcc |
| Line) - Selected Cell | | |
| Gate Electrode 34 (Second | ½ Vpp | Vcc |
| Word Line) - Selected Cell | | |
| Gate Electrode 33′ (First Word | ½ Vpp | Vcc or 0 V |
| Line) - Unselected Cell | | |
| Gate Electrode 34′ (Second | 0 V | 0 V |
| Word Line) - Unselected Cell | | |
| Source Regions 38, 38′ | 0 V | 0 V |

The present invention has the advantage that the OTPROM structure of the present invention is simple with the thickness of the gate insulation layer of the selection transistors being substantially same as that of the fuse insulation layer. This results in a much simpler process for fabricating the OTPROM of the present invention because the misalignment margins need not be added in the fabrication process.

Although the present invention has been described above with respect to several embodiments, various modifications can be made within the scope of the present invention. The present invention is not limited to the specific type of transistors described herein. For example, the selection transistors of the OTPROM may be N channel MOSFETs (Metal-Oxide-Silicon Field Effect Transistors) formed on a P-type substrate or P channel MOSFETs formed on an N-type substrate. The voltages Vpp and Vcc are not limited to the specific values described herein, and a variety of different values may be used for Vpp and Vcc, so long as (i) Vpp is high enough to destroy the fuse insulation layer (i.e., higher than the threshold breakdown voltage of the fuse electrodes), (ii) ½ Vpp is not high enough to destroy the gate insulation layer (i.e., the difference between Vpp and ½ Vpp is lower than the breakdown voltage of the gate insulation layer of the selection transistors), and (iii) Vcc is high enough to turn on the selection transistors (i.e., higher than the threshold turn-on voltages of the selection transistors). The ground (zero) voltage applied to the gate electrode of the selection transistor in the unselected memory cell need not be zero, so long as it is lower than the threshold turn-on voltage of the corresponding selection transistor.

Furthermore, the dimensions of the devices illustrated herein are merely examples, and different sizes or thicknesses of the devices may be used within the spirit of the present invention. In addition, the OTPROM of the present invention can be implemented with a fuse and two selection transistors even with the gate insulation layer and the fuse insulation layer having different thicknesses, although such implementation would complicate the process for fabricating the OTPROM. Accordingly, the disclosure of the present invention is intended to be illustrative, but not limiting, of the scope of the invention, which is set forth in the following claims.

What is claimed is:

1. A one time programmable read-only memory (OTPROM) device having a plurality of memory cells, a memory cell of the one time programmable read-only memory device comprising:
a fuse indicating a first memory state of the memory cell if the fuse is destroyed and a second memory state of the memory cell if the fuse is not destroyed;
a first transistor coupled to the fuse; and
a second transistor serially coupled to the first transistor, wherein both the first transistor and the second transistor are turned on to select the memory cell and at least one of the first transistor and the second transistor are turned off to unselect the memory cell.

2. The one time programmable read-only memory device of claim 1, wherein a first voltage, a second voltage, and a third voltage are applied to a fuse electrode of the fuse, a first gate electrode of the first transistor, and a second gate electrode of the second transistor, respectively, the first voltage being higher than a threshold breakdown voltage of a fuse insulation layer of the fuse and the second voltage and the third voltage being lower than the first voltage, to select the memory cell and destroy the fuse during a write operation to the one time programmable read-only memory device.

3. The one time programmable read-only memory device of claim 2, wherein the third voltage is substantially same as the second voltage.

4. The one time programmable read-only memory device of claim 2, wherein the second voltage and the third voltage are substantially half of the first voltage.

5. The one time programmable read-only memory device of claim 2, wherein a difference between the first voltage and the second voltage is lower than a threshold breakdown voltage of a gate insulation layer of the first transistor.

6. The one time programmable read-only memory device of claim 1, wherein a first voltage, a second voltage, and a third voltage are applied to a fuse electrode of the fuse, a first gate electrode of the first transistor, and a second gate electrode of the second transistor, respectively, the third voltage being lower than both the second voltage and a threshold turn-on voltage of the second transistor, to unselect the memory cell during a write operation to the one time programmable read-only memory device.

7. The one time programmable read-only memory device of claim 6, wherein the third voltage is substantially zero volt.

8. The one time programmable read-only memory device of claim 1, wherein a first voltage, a second voltage, and a third voltage are applied to a fuse electrode of the fuse, a first gate electrode of the first transistor, and a second gate electrode of the second transistor, respectively, the second voltage and the third voltage being higher than threshold turn-on voltages of the first transistor and the second transistor, respectively, to turn on both the first transistor and the second transistor and select the memory cell during a read operation from the one time programmable read-only memory device.

9. The one time programmable read-only memory device of claim 8, wherein the first voltage, the second voltage, and the third voltage are substantially same.

10. The one time programmable read-only memory device of claim 1, wherein a first voltage, a second voltage, and a third voltage are applied to a fuse electrode of the fuse, a first gate electrode of the first transistor, and a second gate electrode of the second transistor, respectively, the third voltage being lower than a threshold turn-on voltage of the second transistor, to unselect the memory cell during a read operation from the one time programmable read-only memory device.

11. The one time programmable read-only memory device of claim 10, wherein the third voltage is zero volt.

12. The one time programmable read-only memory device of claim 10, wherein the second voltage and the third voltage are same.

13. The one time programmable read-only memory device of claim 10, wherein the second voltage is higher than the third voltage.

14. The one time programmable read-only memory device of claim 1, wherein a fuse insulation layer of the fuse is substantially as thick as a first gate insulation layer of the first transistor and a second gate insulation layer of the second transistor.

15. The one time programmable read-only memory device of claim 14, wherein the fuse insulation layer, the first gate insulation layer, and the second gate insulation layer are parts of a common insulation layer.

16. The one time programmable read-only memory device of claim 1, wherein the first transistor and the second transistor are MOSFETs (Metal-Oxide-Silicon Field Effect Transistors).

17. A method of operating a one time programmable read-only memory (OTPROM) device having a plurality of memory cells, a memory cell of the one time programmable read-only memory device including a fuse indicating a first memory state of the memory cell if the fuse is destroyed and a second memory state of the memory cell if the fuse is not destroyed, a first transistor coupled to the fuse, and a second transistor serially coupled to the first transistor, the method comprising:
turning on both the first transistor and the second transistor to select the memory cell; and
turning off at least one of the first transistor and the second transistor to unselect the memory cell.

18. The method of claim 17, further comprising:
applying a first voltage to a fuse electrode of the fuse;
applying a second voltage to a first gate electrode of the first transistor; and
applying a third voltage to a second gate electrode of the second transistor, the first voltage being higher than a threshold breakdown voltage of a fuse insulation layer of the fuse, and the second voltage and the third voltage being lower than the first voltage, to select the memory cell and destroy the fuse during a write operation to the one time programmable read-only memory device.

19. The method of claim 18, wherein the third voltage is substantially same as the second voltage.

20. The method of claim 18, wherein the second voltage and the third voltage are substantially half of the first voltage.

21. The method of claim 18, wherein a difference between the first voltage and the second voltage is lower than a threshold breakdown voltage of a gate insulation layer of the first transistor.

22. The method of claim 17, further comprising:
applying a first voltage to a fuse electrode of the fuse;
applying a second voltage to a first gate electrode of the first transistor; and
applying a third voltage to a second gate electrode of the second transistor, wherein the third voltage is lower than both the second voltage and a threshold turn-on voltage of the second transistor, to unselect the memory cell during a write operation to the one time programmable read-only memory device.

23. The method of claim 22, wherein the third voltage is substantially zero volt.

24. The method of claim 17, further comprising:
applying a first voltage to a fuse electrode of the fuse;
applying a second voltage to a first gate electrode of the first transistor; and
applying a third voltage to a second gate electrode of the second transistor, the second voltage and the third voltage being higher than threshold turn-on voltages of the first transistor and the second transistor, respectively, to turn on both the first transistor and the second transistor and select the memory cell during a read operation from the one time programmable read-only memory device.

25. The method of claim 24, wherein the first voltage, the second voltage, and the third voltage are substantially same.

26. The method of claim 17,
applying a first voltage to a fuse electrode of the fuse;
applying a second voltage to a first gate electrode of the first transistor; and
applying a third voltage to a second gate electrode of the second transistor, the third voltage being lower than a threshold turn-on voltage of the second transistor, to unselect the memory cell during a read operation from the one time programmable read-only memory device.

27. The method of claim 26, wherein the third voltage is zero volt.

28. The method of claim 26, wherein the second voltage and the third voltage are substantially same.

29. The method of claim 26, wherein the second voltage is higher than the third voltage.

30. A one time programmable read-only memory (OTPROM) device comprising:
a plurality of active regions longitudinally formed on a semiconductor substrate of a first conductivity type, the active regions being separated by a plurality of field regions longitudinally formed between the active regions;
a plurality of first gate electrode lines latitudinally formed over the active regions and displaced from the active regions by a first insulation layer formed on the active regions;
a plurality of second gate electrode lines latitudinally formed over the active regions and displaced from the active regions by the first insulation layer;
a plurality of fuse electrodes each formed on a first end of a corresponding one of the active regions and displaced from the active regions by a second insulation layer formed on the active regions, the fuse electrodes and the second insulation layer forming a plurality of fuses;
a plurality of first junction regions of a second conductivity type formed within the active regions under the first insulation layer between the fuse electrodes and the first gate electrode lines;
a plurality of second junction regions of the second conductivity type formed within the active regions under the first insulation layer between the first gate electrode lines and the second gate electrode lines, the first gate electrode lines, the first junction regions, the first insulation layer, and the second junction regions forming a plurality of first transistors; and
a plurality of third junction regions of the second conductivity type each formed within the active regions under the first insulation layer between the second gate electrode lines and a second end of the corresponding one of the active regions, the second gate electrode lines, the second junction regions, the first insulation layer, and the third junction regions forming a plurality of second transistors, and each memory cell of the one time programmable read-only memory device including a corresponding one of the fuses, a corresponding one of the first transistors, and a corresponding one of the second transistors.

31. The one time programmable read-only memory device of claim 30, further comprising:
a plurality of fourth junction regions of the second conductivity type formed within the active regions under the second insulation layer and the fuse electrodes, wherein the fuse electrodes, the second insulation layer, and the fourth junction regions form the fuses.

32. The one time programmable read-only memory device of claim 30, wherein the first insulation layer and the second insulation layer have a substantially same thickness.

33. The one time programmable read-only memory device of claim 30, wherein the first insulation layer and the second insulation are a common layer.

34. The one time programmable read-only memory device of claim 30, wherein the first conductivity type is a P-type and the second conductivity type is an N-type, and the first transistor and the second transistor are MOSFETs (Metal-Oxide-Silicon Field Effect Transistors).

35. A method of fabricating a one time programmable read-only memory (OTPROM) including a fuse, a first transistor coupled to the fuse, and a second transistor serially coupled to the first transistor, the method comprising:
forming an insulation layer on an active region of a semiconductor substrate of a first conductivity type;
simultaneously forming a first gate electrode, a second gate electrode, and a fuse electrode on the insulation layer, the fuse electrode being formed on a first end of the active region; and
simultaneously forming a first junction region, a second junction region, and a third junction region of a second conductivity type, the first junction region being formed within the active region under the insulation layer between the fuse electrode and the first gate electrode, the second junction region being formed within the active region under the insulation layer between the first gate electrode and the second gate electrode, the third junction region being formed within the active region under the insulation layer between the second gate electrode and a second end of the active region,
wherein the fuse electrode and the insulation layer form the fuse;
the first junction region, the first gate electrode, the insulation layer, and the second junction region form the first transistor; and
the second junction region, the second gate electrode, the insulation layer, and the third junction region form the second transistor.

36. The method of claim 35, further comprising:
forming a fourth junction region of the second conductivity type within the active region under the insulation layer and the fuse electrode, wherein the fuse electrode, the insulation layer, and the fourth junction region form the fuse.

37. The method of claim 35, wherein the insulation layer functions as both a fuse insulation layer of the fuse and gate insulation layers of the first transistor and the second transistor.

38. The method of claim 35, wherein the first conductivity type is a P-type and the second conductivity type is an N-type, and the first transistor and the second transistor are MOSFETs (Metal-Oxide-Silicon Field Effect Transistors).

39. A method of fabricating a one time programmable read-only memory (OTPROM) device, the method comprising:
forming a plurality of active regions longitudinally on a semiconductor substrate of a first conductivity type, the active regions being separated by a plurality of field regions longitudinally formed between the active regions;
forming an insulation layer on the active regions;
simultaneously forming a plurality of first gate electrode lines, a plurality of second gate electrode lines, and a plurality of fuse electrodes, the first gate electrode lines and the second gate electrode lines being latitudinally formed on the insulation layer, the fuse electrodes each being formed on a first end of a corresponding one of the active regions on the insulation layer, and the fuse electrodes and the insulation layer forming a plurality of fuses;
simultaneously forming a plurality of first junction regions, a plurality of second junction regions, and a plurality of third junction regions of a second conductivity type, the first junction regions being formed within the active regions under the insulation layer between the fuse electrodes and the first gate electrodes, the second junction regions being formed within the active regions under the insulation layer between the first gate electrodes and the second gate electrodes, the third junction regions each being formed within the active regions under the insulation layer between the second gate electrodes and a second end of the corresponding one of the active regions,
wherein the fuse electrodes and the insulation layers form a plurality of fuses;
the first junction regions, the first gate electrodes, the insulation layer, and
the second junction regions form a plurality of first transistors;
the second junction regions, the second gate electrodes, the insulation layer, and the third junction regions form a plurality of second transistors; and
each memory cell of the one time programmable read-only memory device includes a corresponding one of the fuses, a corresponding one of the first transistors, and a corresponding one of the second transistors.

40. The method of claim 39, further comprising:
forming a plurality of fourth junction regions of the second conductivity type within the active regions under the insulation layer and the fuse electrodes, wherein the fuse electrodes, the insulation layer, and the fourth junction regions form the fuses.
